(19) United States
(12) Patent Application Publication
(10) Pub. No.: US 2005/0170570 A1
(43) Pub. Date: Aug. 4, 2005

(54) High electrical quality buried oxide in simox

(75) Inventors: Joel P. DeSouza, Putnam Valley, NY (US); Keith E. Fogel, Mohegan Lake, NY (US); Harold J. Hovel, Katonah, NY (US); Junedong Lee, Hopewell Junction, NY (US); Siegfried L. Maurer, Stormville, NY (US); Devendra K. Sadana, Pleasantville, NY (US); Dominic J. Schepis, Wappingers Falls, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, ARMONK, NY (US)

(21) Appl. No.: 10/768,341

(22) Filed: Jan. 30, 2004

(51) Int. Cl. H01L 21/00; H01L 21/84

(52) U.S. Cl. 438/162; 438/149

(57) ABSTRACT

A SIMOX (separation by implanted oxygen) process is provided that forms a silicon-on-insulator (SOI) substrate having a buried oxide with improved electrical properties. The process implements at least one of the following processing steps into SIMOX: (I) lowering of the oxygen ion dose in the base oxygen ion implant step; (II) off-setting the implant energy of the room temperature (RT) implant step to a value that is about 5 to about 20% lower than the base ion implant step; and (III) creating a soak cycle, i.e., pre-annealing step, prior to the internal oxidation anneal which allows dissolution of Si and SiOₓ precipitates in the oxygen implanted region. The temperature and time of the soak cycle as well as the base implant dose are critical in determining the final BOX quality.

### FIELD OF THE INVENTION

The present invention relates to silicon-on-insulator (SOI) substrates for use in the semiconductor industry, and more particularly to methods of forming SOI substrates wherein the buried oxide region has specific high breakdown properties when subjected to process damage and high-degree of process-induced charging.

### BACKGROUND OF THE INVENTION

Separation by implanted oxygen (SIMOX) is one technique that is typically employed in fabricating SOI substrates that can be used in the manufacturing of integrated circuits (ICs). SIMOX typically involves using high-energy ions to implant oxygen ions beneath the surface of a bulk silicon substrate. During a subsequent high temperature annealing step which follows the implantation of oxygen ions, the implanted oxygen forms a layer of buried oxide (BOX) which electrically isolates a top silicon layer (i.e., the SOI layer) of the substrate from a bottom silicon layer.

The implantation and annealing conditions used during the SIMOX process determines the quality of the resulting SOI and BOX layers, which are very critical for semiconductor applications. U.S. Pat. Nos. 5,930,643 to Sadana, et al., 5,989,981 to Nakashima, et al., 6,090,689 to Sadana, et al. and 6,222,253 to Sadana, et al. describe typical prior art SIMOX processes that can be used to form SOI substrates.

Despite the fact that SIMOX techniques are well known, the electrical properties of the BOX are generally such that is designed at a thickness and breakdown field for normal process and operation voltages. Although others may have produced BOX layers with good dielectric properties, the methods to produce BOX layers in SIMOX with extremely high dielectric properties after processing induced damage has not been documented. This is because in most cases, the BOX layer is never exposed directly to the processing ambient since it usually is covered with a silicon layer or a dielectric layer in the isolation regions.

As SOI complementary metal oxide semiconductor (CMOS) layers get thinner and the BOX layer becomes closer to the top surface of the substrate, it becomes vulnerable to certain processes, such as, for example, shallow trench formation, during which thinning of the top portion of the BOX can occur. The BOX thinning makes it susceptible to breakdown. This problem did not surface previously since thicker SOI layers (on the order of about 120 nm or greater) protected the BOX. Furthermore, certain plasma processes are known to cause BOX breakdown via charging through the BOX in the areas where BOX damage has originally occurred. While it could be argued that other methods exist for solving this problem, for example, a thicker BOX (on the order of about 200 nm or greater), it is clear that these methods have many disadvantages. The primary one being that a thick BOX requires a much higher dose of oxygen implant, leading to a much longer and much more costly process.

The problem mentioned above with prior art SIMOX processes is now illustrated in more detail with reference to a conventional process that includes two ion implantation steps and a subsequent high temperature annealing step, see, for example, U.S. Pat. No. 5,930,643 to Sadana, et al. In this SIMOX process, a semiconductor substrate receives the first implant, so called ‘base dose implant’, of oxygen ions at an energy of about 40 to 240 keV using a dose of about 1E16 to 4E17 cm⁻². The substrate is kept at about 200°-600° C. during this base implant step. For the second implant step, the substrate temperature is maintained at room temperature (RT). The RT implant of oxygen is typically carried out using a lower dose of about 5E14 to 1E16 cm⁻², but at the same energy as the base dose.

The RT implant acts to amorphize the silicon layer at that depth specified by the energy. The amorphized layer helps in the formation of a continuous BOX and it enhances internal thermal oxidation (ITOX) during the high temperature annealing. This leads to a BOX structure that consists of two regions: (1) a top region, which is as good as a thermal oxide since it is formed by ITOX, and (ii) a bottom region where most of the implanted oxygen forms the oxide. This latter region contains non-stoichiometric SiO₂ that has inferior electrical qualities.

Typically, the electrical quality of the BOX in commercial SIMOX is inferior to that of a thermal oxide. Electrical quality of a BOX is defined by the breakdown field (Ebd) of the oxide. For a thermal oxide of greater than about 1000 Å, Ebds of greater than about 8 MV/cm are typically achieved for a thermal oxide. Furthermore, when depth profiling of this oxide is performed, there is almost no change in the breakdown field even though the breakdown voltage decreases linearly with the decreasing thickness. However, in commercial SIMOX, Ebd of the best-known full BOX is typically less than about 7 MV/cm. The depth profiling of this latter BOX shows a steep decline in Ebd as the BOX thickness decreases below 1000 Å. Typical Ebd values of less than 2-3 MV/cm are obtained in thinned SIMOX. The foregoing is why SIMOX wafers often show significant BOX degradation after process damage during the device fabrication (for example, BOX erosion by STI polishing or process charging).

In view of the above, there is a need for providing new SIMOX processes that lead to improvements in the BOX breakdown, not just a full thickness, but even at the thinned damaged state.

### SUMMARY OF THE INVENTION

The present invention is aimed at improving the electrical quality of the entire BOX in SIMOX to that which is comparable to a thermal oxide. As stated above, the BOX of a SIMOX wafer essentially consists of two regions (i) a top region that is as good as a thermal oxide since it is formed by ITOX, and (ii) a bottom region where most of the implanted oxygen forms the oxide. The latter region contains non-stoichiometric SiO₂ which has inferior electrical quality as compared to the top region.

All prior art attempts to improve the electrical quality of region (ii) have only succeeded marginally. This is because the implanted doses and heat cycles used for SIMOX are designed to grow ITOX on top of the implanted oxide rather efficiently to grow a uniform BOX. The commercial SIMOX process was not designed to create a stoichiometric oxide in region (ii). However, recent application of SIMOX with a thin SOI (on the order of about 70 nm or less) and a thin BOX (on the order of about 100 nm or less) has highlighted the need for a uniformly good BOX. The present invention enhances the electrical quality of region (ii) by a SIMOX process wherein at least one of the following processing steps is implemented: (I) lowering of the oxygen ion dose in the base oxygen ion implant step; (II) off-setting the implant energy of the RT implant step to a value that is about 5 to about 20% lower than the base ion implant step; and (III) creating a soak cycle, i.e., pre-annealing step, prior to the ITOX anneal which allows dissolution of Si and SiOₓ precipitates in the oxygen implanted region. The temperature and time of the soak cycle as well as the base implant dose are critical in determining the final BOX quality.

In a highly preferred embodiment of the present invention, Steps (II) and (III) are implemented. In yet another embodiment of the present invention, Step (III) is implemented. In still yet another highly preferred embodiment of the present invention, all three of the aforementioned processing steps, i.e., Steps (I), (II) and (III), are implemented. It is emphasized that when a SIMOX process using step (III) of the present invention, the electrical quality of the BOX region is substantially improved, especially in the lower region of the BOX, since the soak cycle, i.e., pre-annealing step, prior to the ITOX anneal allows dissolution of Si and SiOₓ precipitates in the oxygen implanted region.

Results show that the process of the present invention which includes at least one, more preferably at least two, and even more preferably all three, of the above mentioned processing steps provides an SOI substrate in which the BOX has electrical qualities that are equivalent to that of a thermal oxide. Specifically, the SIMOX process of the present invention typically produces a BOX having a breakdown field of greater than about 8 MV/cm at its full thickness of 1300-1600 Å and a breakdown field of greater than about 5 MV/cm at a thickness of greater than 900 Å, i.e., thinned BOX.

While some traditional SIMOX processes perform all the implant steps at the same energy, the present invention as described above in Steps (I) and (II) uses energies that are differentiated from one another, leading to new properties for the BOX. The exact combination of dose and energy and the offset between the two implants is key in producing improved BOX SIMOX. The improvement in the quality in the middle of the box region makes it particularly suited for process damaging environments.

It addition to the above SIMOX processing steps, the applicants have also determined that the ITOX region of the BOX can be increased by lowering the anneal temperature to a temperature of less than about 1320° C. This relationship is different from the previous one mentioned in the prior art wherein it was thought that the ITOX region of a BOX could be increased by increasing the annealing temperature.

### BRIEF DESCRIPTION OF THE DRAWINGS

FIGS. 1A-1D are pictorial representations (through cross sectional views) illustrating the fabrication of an SOI substrate having a continuous BOX region of improved electrical quality during various processing steps of the present invention.

FIGS. 2A-2D are pictorial representations (though cross sectional views) illustrating the fabrication of an SOI substrate having a patterned BOX region of improved electrical quality during various processing steps of the present invention.

FIG. 3 is a graph showing the effect of the RT implant dose on BOX thickness and its breakdown field at 900 Å.

FIG. 4 is a graph showing the effect of ITOX temperature on BOX thickness.

FIG. 5 is a graph showing breakdown field and BOX thickness versus dose.

FIG. 6 is a graph of BOX breakdown field as a function of the remaining Si thickness for the process of the present invention (Curve X) and for various prior art processes (Curves A and B.)

### DETAILED DESCRIPTION OF THE INVENTION

The present invention, which provides a SIMOX process for fabricating an SOI substrate having a BOX region (continuous or patterned) of improved electrical quality, will now be described in greater detail by referring to the following discussion. It should be noted that the following discussion describes an embodiment of the present invention in which the SIMOX process includes all three of the processing steps mentioned above, i.e., Steps (I), (II) and (III). Although illustration is made for the embodiment in which Steps (I), (II) and (III) are each employed, the present invention also contemplates embodiments wherein one or two of Steps (I), (II) or (III) are employed. In those embodiments in which Steps (I), (II) or (III) are not employed, conventional SIMOX implant and/or annealing conditions such as described and disclosed, for example, in U.S. Pat. Nos. 5,930,643, 5,989,981, 6,090,689 or 6,222,253 can be employed. The contents of each of the aforementioned U.S. Patents are incorporated herein by reference.

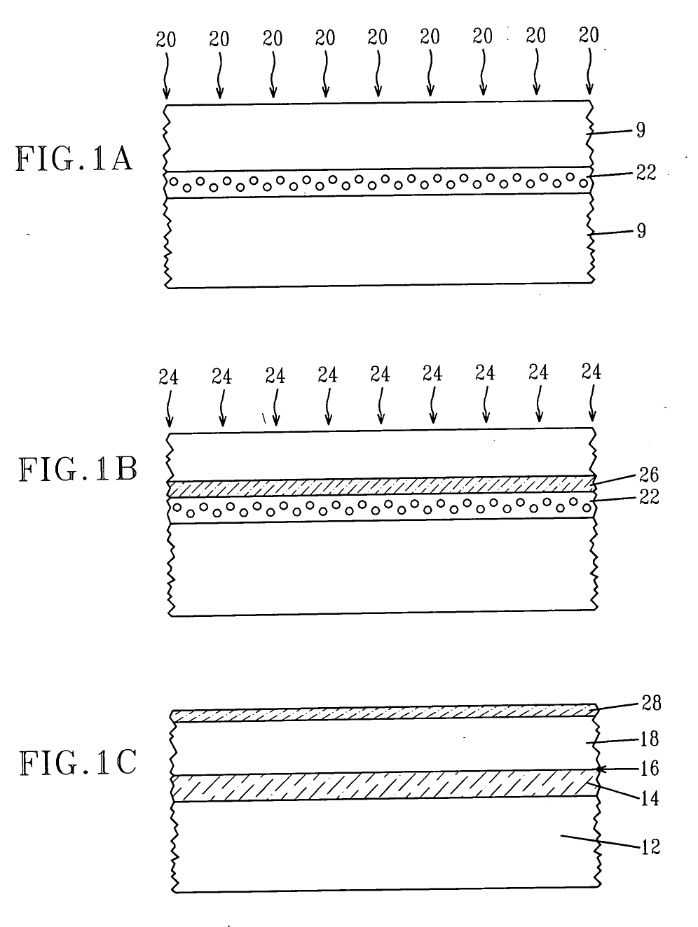

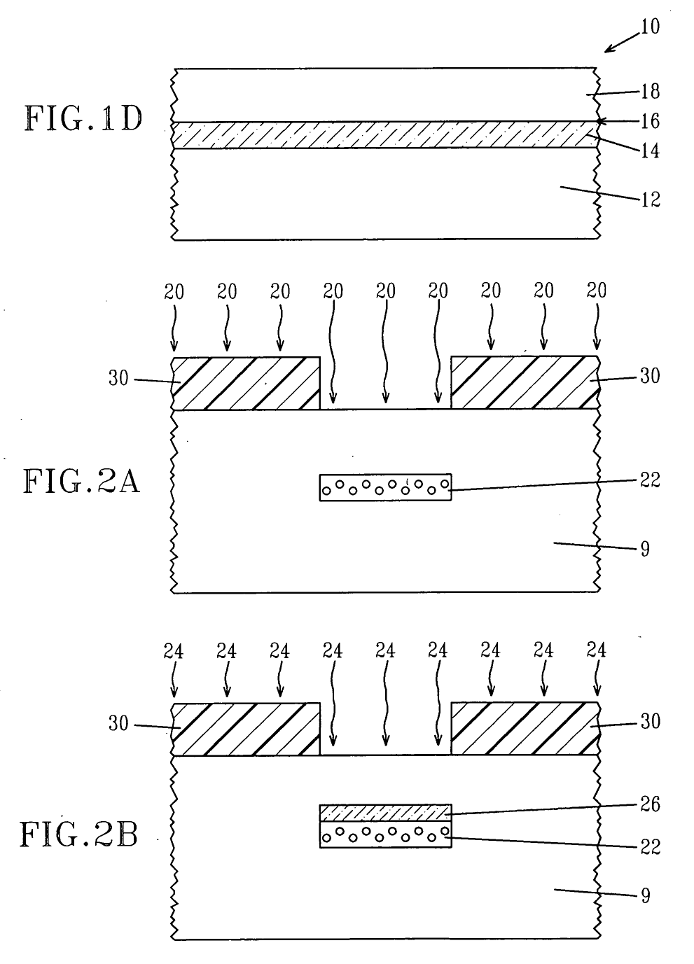

As indicated above, the present invention provides improved SIMOX processes including at least one of Steps (I), (II) or (III), especially Step (III) only or in combination with Step (II), wherein an SOI substrate having a BOX region of improved electrical quality, i.e., breakdown field, is fabricated. The SOI substrates 10, See FIGS. 1D and 2D, produced by the SIMOX processes of the present invention comprise a buried oxide (BOX) region 14 that is located between a top Si-containing layer 18 and a bottom Si-containing layer 12. In accordance with the present invention, the BOX region of the present invention has improved breakdown properties as compared with prior processes of producing equivalent SOI substrates. In particular, the BOX region of the present invention has breakdown properties that are characteristic of a thermal oxide. The BOX regions having the thermal oxide characteristic have a breakdown field of 8 MV/cm for a thickness of greater than 500 Å to 10 MV/cm for BOX regions having a thickness of 500 Å or less.

In addition to the improved breakdown properties, the BOX region includes an interface 16 that is uniform with the top Si-containing layer 18 of the SOI substrate 10. The term “uniform” is used herein to denote that the BOX region of the present invention is smooth, not rough, as is typically the case with most prior art SOI substrates. In the embodiment shown in FIG. 1D, the SOI substrate 10 contains a BOX region 14 that is continuously present throughout the entire substrate 10. Thus, no measurable voids exists between the BOX region 14 and the top Si-containing layer 18 of the SOI substrate 10 shown in FIG. 1D. In the embodiment shown in FIG. 2D, a discrete BOX region 14 is present in the SOI substrate 10.

The thickness of the BOX region formed in the present invention may vary depending upon the exact embodiments and conditions (implant and anneal) used in fabricating the same. Typically, however, the BOX region of the present invention has a thickness from about 1200 to about 1800 Å, with a BOX thickness from about 1300 to about 1600 Å being more typical.

Insofar as the top Si-containing layer 18 of the SOI substrate 10 is concerned, that Si-containing layer may have a variable thickness, which is also dependent on the embodiment and conditions used in fabricating the SOI substrate. Typically, however, the top Si-containing layer 18 of the SOI substrate 10 has a thickness from about 10 to about 1000 Å, with a top Si-containing layer thickness from about 200 to about 700 Å being more typical. The thickness of the bottom Si-containing layer 12 of the SOI substrate 10 is inconsequential to the present invention.

The SOI substrate of the present invention can be used in forming high-performance semiconductor devices or circuits. Examples of such devices or circuits that can contain the SOI substrate of the present invention include, but are not limited to: microprocessors, memory cells such as dynamic random access memory (DRAM) or static random access memory (SRAM), application specific integrated circuits (ASICs), optical electronic circuits, and larger and more complicated circuits. Since these devices or circuits are well known to those skilled in the art, it is not necessary to provide a detail description concerning the same herein. It is however emphasized that the active devices and/or circuits of such semiconductor devices and circuits are typically formed in the top Si-containing layer of the SOI substrate of the present invention.

The term “Si-containing” when used in conjunction with layers 12 and 18 as well as the initial substrate 9 used prior to performing SIMOX denotes any semiconductor material that includes silicon therein. Illustrative examples of such Si-containing materials include but are not limited to: Si, SiGe, SiGeC, SiC, Si/Si, Si/SiGe, preformed SOI wafers, silicon germanium-on-insulators (SGOI) and other like semiconductor materials. The preformed SOI wafers and SGOI wafers, which can be patterned or unpatterned, may also include a single or multiple buried oxide regions formed therein. The Si-containing material can be undoped or doped (p or n-doped) depending on the future use of the SOI substrate. The crystal orientation of the starting Si-containing substrate used in the improved SIMOX process of the present invention can vary depending on the future use of the fabricated SOI substrate.

Reference is now made to FIGS. 1A-1D which show basic processing steps of the present invention that are employed in forming an SOI substrate having a continuous (i.e., unpatterned) buried oxide region of improved electrical quality. It is again emphasized that in the embodiment shown the SIMOX process includes (I) a base oxygen ion implantation step wherein the ion dose of the base oxygen ion is lowered as compared to base ion implantation steps described in the prior art; (II) an RT implant step wherein the implant energy is off-set to a value that is about 5 to about 20% lower than the base ion implant step; and (III) a soak cycle step, i.e., pre-annealing step, carried out prior to the ITOX anneal which allows dissolution of Si and SiOₓ precipitates in the oxygen implanted region. Despite illustrating a SIMOX process wherein Steps (I), (II), and (III) are implemented, SOI substrates having BOX regions of improved electrical quality can also be achieved in cases in which at least one of Steps (I), (II) or (III) are implemented.

FIG. 1A shows an initial Si-containing substrate 9 being irradiated with oxygen ions 20 using a base oxygen ion implant step. Whereas low and medium SIMOX processes use a base oxygen ion dose from about 3E17 to about 1E18 cm⁻² at an energy from about 170 to about 210 keV, the SIMOX process of the present invention in which Step (I) is employed uses a base oxygen ion dose that is less than the low and medium SIMOX processes mentioned above. In particular, when Step (I) is employed, the base oxygen implant step is performed using an oxygen dose of about 2.5E17 cm⁻² or less at an energy of about 170 keV or greater, with an oxygen ion dose from about 2.0E17 to about 2.4E17 cm⁻² being more preferred. The base ion implant step can be done in a single step, or multiple implant steps can be used (the total oxygen doses used in the multiple base ion implantations does not exceed an ion concentration of 2.5E17 cm⁻²). When Step (I) of the present invention is not used, the base ion implant doses utilized are within conventional ranges well known to those skilled in the art.

The base oxygen implant step is carried out in an ion implantation apparatus that operates at a beam current from about 1 to about 100 milliamps and at energies that range from about 1 to about 10,000 keV. More preferably, the base oxygen ion implant step is carried out using an energy from about 40 to about 240 keV.

The base oxygen ion implant step is carried out at a substrate temperature from about 100° to about 800° C., with a substrate temperature from about 200° to about 600° C. being more preferred.

During the course of the base oxygen ion implant step, an implanted damaged region 22 as shown in FIG. 1A, is formed by the implanted oxygen ions. The oxygen ions 20 are typically implanted into the initial Si-containing substrate 9 to a depth from about 1000 to about 6000 Å, with a depth from about 3500 to about 5000 Å being more typical. The depth is measured from the top surface of the Si-containing substrate 9 and it represents a mean value that is based upon a Gaussian distribution.

Next, and as shown in FIG. 1B, Step II of the present invention, i.e., an RT implant step wherein the implant energy of oxygen ions 24 is off-set to a value that is about 5 to about 20% lower than the base ion implant step, is employed. When Step (II) is not employed, any conventional ion implantation step which is performed at a lower substrate temperature than the base ion temperature step that can form an amorphized implant region adjacent to the damaged implant region 22 can be employed.

Step (II) of the present invention, which includes an RT implant wherein the implant energy is off-set to a value that is about 5 to about 20% lower than the base ion implant step, forms an adjacent amorphized implant region 26 which is connected to the damaged implant region 22. Although, FIG. 1B shows the adjacent amorphized implant region 26 to be shallower than the damaged implanted region 22 formed by the base ion implantation step, the amorphized implant region 26 can be at the same or deeper depth than the damaged implant region 22. The amorphized implant region 26 can also be referred to herein as an oxygen ion rich region.

The RT implantation step can be done in a single step, or multiple implant steps can be used.

The RT implantation step of the present invention, i.e., Step (II), is performed using a low temperature/low dose ion implantation step. As indicated above, Step (II) of the present invention is performed using an implant energy that is about 5 to about 20%, preferably from about 6 to about 8%, less than the energy used in the base ion implant step. Typically, the RT implantation step of the present invention is performed at an implant energy from about 155 to about 165 keV. Performing the RT implant at a lower energy than the base ion implant step is believed to result in a higher quality BOX formation that is away from the peak ion implant region. This may, in turn, minimize the formation of Si inclusions in the BOX during the ITOX annealing step.

The RT implantation step of the present invention is typically carried out using an oxygen dosage from about 1E15 to about 5E15 cm⁻², with a dosage from about 2E15 to about 4E15 cm⁻² being more typical. The RT implantation step is performed at a substrate temperature from about 1 Kelvin (1K) to about 200° C., with the proviso that the temperature of the RT is less than the base ion implantation step. More specifically, the RT implantation step is performed at a temperature from about 20° to about 100° C. The RT implant is performed in an ion beam apparatus having a beam density within the range mentioned above in connection with the base ion implantation step.

The oxygen ions 24 used in forming the amorphized implant region 26 are typically implanted into the initial Si-containing substrate 9 to a depth from about 3000 to about 3700 Å. The depth is measured from the top surface of the Si-containing substrate 9 and it represents a mean value that is based upon a Gaussian distribution.

In some embodiments of the present invention, not shown, a Si-containing or Ge-containing layer is formed atop the surface of the initial Si-containing substrate at this point of the present invention. The Si-containing layer employed in this embodiment of the present invention includes SiGe (high Si content compared to Ge), SiC, SiGeC, amorphous Si, polycrystalline Si (i.e., polySi), epitaxial Si (i.e., epi Si), defective Si containing stacking faults and microtwins or combinations and multilayers thereof. The Ge-containing layer includes pure Ge or a Ge alloy such as SiGe (high Ge content as compared to Si).

The optional Si-containing or Ge-containing layer can be formed using a conventional deposition process well known to those skilled in the art. For example, the optional Si-containing or Ge-containing layer can be formed by chemical vapor deposition (CVD), plasma-enhanced chemical vapor deposition (PECVD), low-pressure chemical vapor deposition (LPCVD), sputtering, evaporation, or chemical solution deposition. Alternatively, the optional Si-containing or Ge-containing layer can be formed by a conventional epitaxial growth process.

The thickness of the optional Si-containing or Ge-containing layer formed on the implanted Si-containing substrate may vary depending upon the type of layer employed as well as the process used in forming the same. Typically, the optional Si-containing or Ge-containing layer has a thickness from about 50 to about 25,000 Å, with a thickness from about 100 to about 5000 Å being more typical.

Following the RT ion implantation step or optional formation of the Si-containing or Ge-containing layer, the structure is then subjected to an annealing process. The annealing process can include a conventional anneal which includes a ramp-up step in a low-oxidizing ambient, an ITOX step in a high-oxidizing ambient, an annealing step in an low-oxidizing ambient, and a ramped-down step in a low-oxidizing ambient. The conditions for the conventional anneals are well known in the art and they are capable of converting the amorphized implant region 26 and the damaged implant region 22 into a BOX region. In the embodiment in which the SIMOX process of the present invention includes Step (III) mentioned above, a prolonged pre-annealing step is employed prior to the ITOX step. Specifically, the annealing step of the present invention, which is typically performed in a furnace, is performed utilizing the following steps:

(i) A ramp-up step in which the implanted substrate is ramped from room temperature to a temperature of about 1300° C. is first employed. The ramp-up is typically performed utilizing a ramp-up rate from about 0.01 to about 0.2° C./min, with a ramp-up rate from about 0.05 to about 0.1° C./min being more typical. The ramp-up is performed in a low-oxidizing ambient. By “low-oxidizing”, it is meant an ambient such as an inert gas ambient (He, Ar, N₂, and mixtures thereof) wherein the oxygen content is less than 10%. The time for the ramp-up step is dependent upon the desired final temperature as well as the rate used to obtain the same.

(ii) Following the ramp-up step, the substrate is then subjected to a pre-annealing soak step. This step is not employed in prior art SIMOX processes. The pre-annealing soak is performed at a temperature of about 1250° C. or greater. More preferably, the pre-annealing soak is performed at a temperature from about 1280° to about 1320° C. The pre-annealing soak is carried out at the desired temperature for a period of time from about 5 minutes to about 5 hours, with a soak time from about 1 hour to about 5 hours being more typical. The pre-annealing soak is performed in a low-oxidizing ambient that can be the same or different than the low-oxidizing ambient used in the ramp-up step. This step of the annealing process of the present invention is believed to dissolve non-stoichiometric SiO_{X} precipitates thereby improving the electrical quality of the BOX, especially in the lower BOX region, i.e., implanted oxide region.

(iii) Following the pre-annealing soak step, the implanted structure is subjected to an ITOX step, which is performed at a temperature from about 1250° C. or greater. More preferably, the ITOX step is performed at a temperature from about 1280° to about 1325° C. ITOX is achieved during the ramp from 1300° C. to 1325° C. at a ramp-up rate from about 0.05 to about 0.1°/min. The ITOX step is performed in a high-oxidizing ambient. By “high-oxidizing”, it is meant an ambient such as an inert gas ambient (He, Ar, N₂, and mixtures thereof) wherein the oxygen content is 30% or greater, preferably 70% or greater.

Following the ITOX step, the implanted substrate is annealed at a temperature from about 1300° C. or greater. More preferably, the annealing step is performed at a temperature from about 1320° to about 1350° C. The annealing step is carried out at the desired temperature for a period of time from about 1 hour to about 20 hours, with a time period for annealing from about 5 to about 10 hours being more typical. The annealing step is performed in a low-oxidizing ambient that can be the same or different from the low-oxidizing ambients used in steps (i) or (ii).

Next, the implanted substrate is then cooled down to room temperature using a ramp-down step. The ramp-down is performed utilizing a cooling rate from about 0.05 to about 5° C./min, with a cooling rate from about 0.1 to about 0.5° C./min being more typical. The ramp-down is performed in a low-oxidizing ambient that can be the same or different from the low-oxidizing ambients used in steps (i), (ii) and (iv).

The annealing process described above which includes the pre-annealing soak step was determined to enhance the electrical quality of the lower part of the BOX. The pre-annealing step allows for dissolution of Si and SiOₓ precipitates in the oxygen implanted regions, especially in the deeper BOX region. The temperature and time of the pre-annealing soak and the base ion implant dose was found to be extremely critical in determining the final BOX quality.

FIG. 1C shows the SOI substrate that is formed after the above-mentioned annealing process has been performed. As shown, the annealing process includes the formation of a surface oxide layer 28 as well as the conversion of implant regions 22 and 26 into BOX region 14. The BOX region formed has improved electrical quality, in terms of breakdown field, as compared to prior art processes that do not include at least one of Steps (I)-(III). Moreover, the BOX region 14 has an interface 16 that is uniform with the thus formed top Si-containing layer 18. As shown, the BOX region 14 electrically isolates the top Si-containing layer 18 from the bottom Si-containing layer.

FIG. 1D shows the SOI substrate after the surface oxide layer 28 has been removed from the structure. The removal of the surface oxide layer which forms during ITOX is performed utilizing a planarization process such as chemical mechanical polishing or grinding or an etching process that is highly selective in removing oxide as compared to Si can be employed to strip the surface oxide layer 28 from the SOI substrate. The surface oxide layer prior to stripping has a thickness from about 500 to about 1500 nm. In some embodiments, the surface oxide may remain atop the top Si-containing layer 18.

FIGS. 2A-2D show an embodiment of the present invention in which a patterned masking material or patterned dielectric cap 30 is used in forming an SOI having a discrete, i.e., patterned, BOX region. This embodiment of the present invention is similar to the embodiment described above except that a patterned masking material or patterned dielectric cap 30 is formed on the top surface of the initial Si-containing substrate prior to the base ion implantation step. The patterned masking material or dielectric cap is formed by deposition, lithography and etching. The patterned masking material or dielectric cap can be removed after either the RT implant or after the annealing step. In the process flow shown in FIGS. 2A-2D, the patterned masking material is removed after the RT implant prior to annealing.

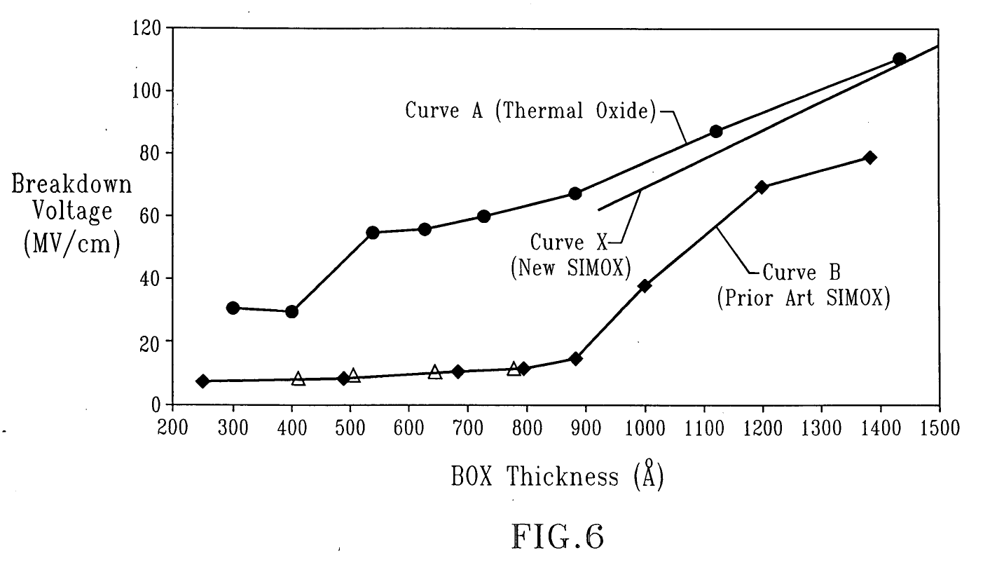

Table 1 shows the effect of the above mentioned pre-annealing soak step and base dose on BOX quality. Specifically, Table 1 shows the Vbd and Ebd of the BOX with and without the pre-anneal soak step. A dramatic increase (˜x2) in Ebd and Vbd are obtained compared when the extended pre-anneal step is introduced in conjunction with lowering of base dose. As stated above, the soak improves the electrical quality of the lower BOX region. FIG. 6 shows that the improved BOX process (defined as Curve X) has electrical quality, which is equivalent to that of a thermal oxide (defined as bonded SOI).

TABLE 1
Effect of pre-anneal and base dose on BOX quality

| | | BOX | BOX | |
|---|---|---|---|---|
| | Pre-anneal | thickness, | thinned | Ebd |
| Base dose | (Soak) | (Å) | (Å) | (MV/cm) |
| 2.5E17 | No | 1772 | 958 | 4.0 |
| 2.5E17 | Yes | 1723 | 922 | 7.1 |
| 2.2E17 | Yes | 1626 | 886 | 8.0 |

In Table 1, the initial BOX thickness is the BOX thickness after SIMOX which includes the SOI layer thereon. The BOX thinned is the thickness of the BOX after removing the SOI layer by KOH or another like chemical etchant to expose the BOX region and thinning the exposed BOX region using dilute HF.

It should be also noted that the lower base dose resulted in higher Ebd of the BOX. Lower base dose create less implantation damage and in turn leave less defects in BOX. Although lower base dose make BOX electrically hard, it obviously makes BOX thinner.

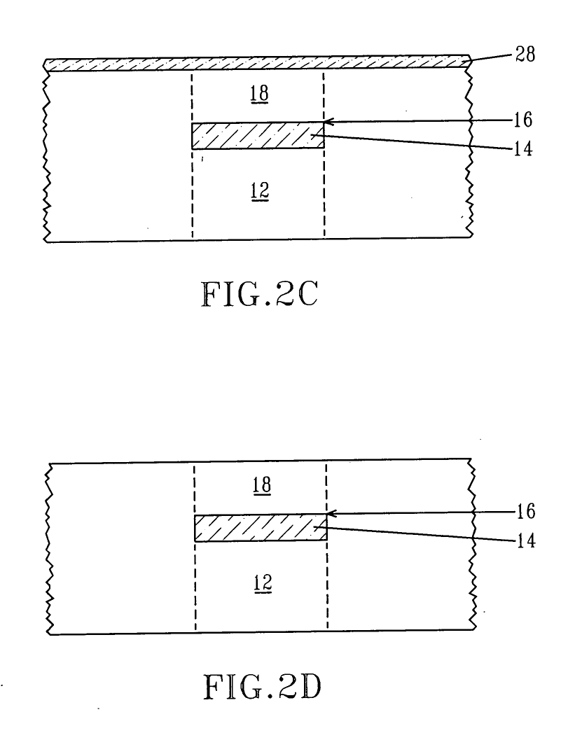

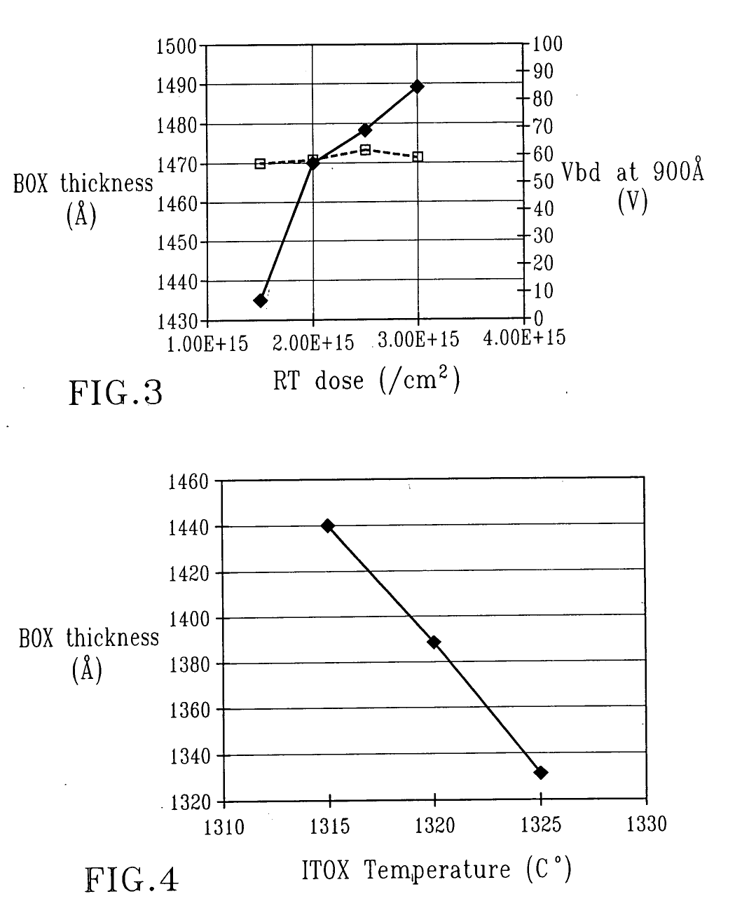

It was found that increasing RT implant dose thickens the BOX as shown in FIG. 3. It is also shown that the electrical quality of BOX is not significantly affected by the RT dose change. Another parameter that can affect BOX thickness is the temperature where ITOX occurs as shown in FIG. 4. Contrary to previously published and disclosed data, ITOX increases as the anneal temperature is reduced. Optimization of the final BOX quality therefore requires careful consideration of all the parameters mentioned above.

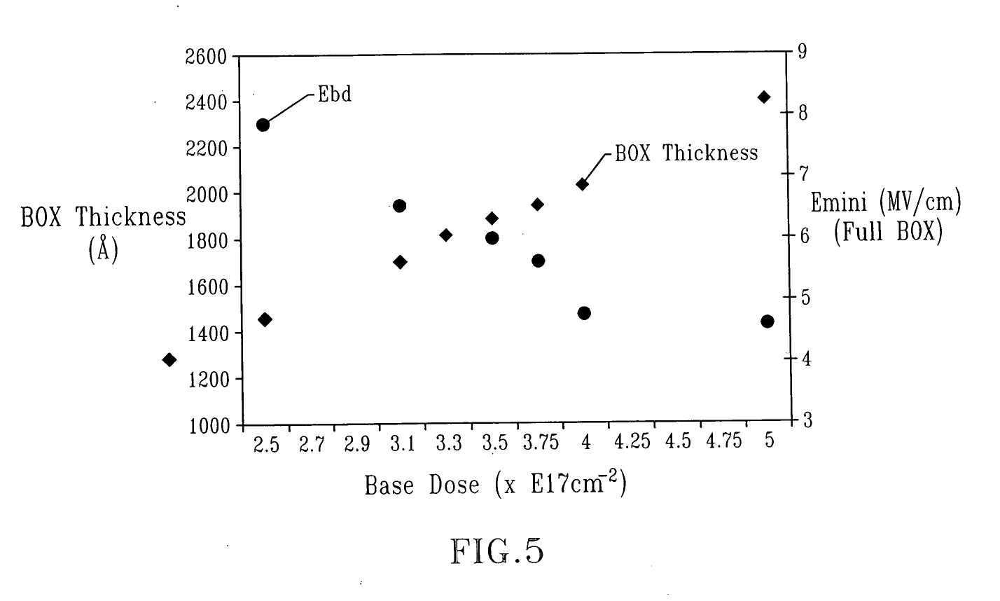

FIG. 5 shows the effect of Ebd and BOX thickness vs. dose. Specifically, FIG. 5 shows that BOX thickness increases with increased dose, while lowering the dose improves BOX quality. The results in FIG. 5 are full BOX thickness, but similar results will be achieved for a thinned BOX.

The following example provides an illustration of the improved SIMOX process of the present invention. The process sequence described in the example was used to produce an SOI substrate with a nominal Si thickness of about 700 Å and a high field BOX thickness of about 1450 Å. Note that the following represents only one example and other conditions that follow within the ranges mentioned above can be used which provide similar results.

### EXAMPLE

An SOI wafer having a nominal Si thickness of about 700 Å and a high voltage BOX thickness of about 1450 Å was produced using the following processing steps:
Starting bulk (100) Si substrate;
Base dose oxygen implant: dose 2.1E17, energy 170 keV, wafer temperature 365° C.;
Room temperature implant: dose 2.5E15, energy 158 keV, wafer temperature 25° C.;
Pre-anneal 1300° C., 2 hours, argon ambient with less than 5% oxygen;
ITOX anneal: 1300°-1320° C., 8 hours, argon ambient with about 50% oxygen;
anneal: 1320° C., 5 hours, argon ambient with less than 5% oxygen; and
strip surface oxide layer.

The above processing steps, which are representative of the present invention, achieved a BOX with increased breakdown through the entire BOX thickness. A graph of the BOX breakdown of the improved SIMOX process of the present invention is shown in FIG. 6. In FIG. 6, Curve X denotes the process of the present invention. In addition to showing the results of the present invention, FIG. 6 also shows the breakdown field of some typical prior art processes, bonding and SIMOX processes. Specifically, Curve A is for a thermal oxide process wherein two Si wafers are bonded together; and Curve B is for a conventional SIMOX process.

While the present invention has been particularly shown and described with respect to preferred embodiments thereof, it will be understood by those skilled in the art that the foregoing and other changes in forms and details may be made without departing from the scope and spirit of the present invention. It is therefore intended that the present invention not be limited to the exact forms and details described and illustrated, but fall within the scope of the appended claims.

1. A method for fabricating a silicon-on-insulator (SOI) substrate comprising the steps of:
(a) subjecting a Si-containing substrate to a base oxygen ion implantation step to create a first structure having a damaged implant region within the Si-containing substrate;
(b) subjecting the first structure to a room temperature oxygen ion implantation step to create a second structure having an amorphized implant region adjacent to said damaged implanted region; and
(c) performing an annealing process on said second structure, wherein at least one of steps (a)-(c) is performed under conditions that are capable of providing an SOI substrate comprising a buried oxide having a breakdown field of greater than 5 MV/cm, with the proviso that when step (a) is selected to achieve said breakdown field the base oxygen ion implantation step is performed using an oxygen ion dose of about 2.5E17 cm⁻² or less, when step (b) is selected to achieve said breakdown field the room temperature oxygen implant step is performed at an energy that is about 5 to about 20% less than an energy used during the base oxygen ion implantation step, or when step (c) is selected to achieve said breakdown field a pre-annealing soak cycle is employed prior to an internal oxidation step.

2. The method of claim 1 wherein steps (b) and (c) are selected to achieve said breakdown field.

3. The method of claim 1 wherein steps (a)-(c) are selected to achieve said breakdown field.

4. The method of claim 1 wherein step (c) is selected to achieve said breakdown field.

5. The method of claim 1 further comprising providing a patterned masking material or dielectric cap to said Si-containing substrate prior to performing step (a).

6. The method of claim 5 wherein said patterned masking material or dielectric cap is removed after performing step (b) or after performing step (c).

7. The method of claim 1 wherein the base oxygen ion implantation step is performed utilizing a single ion implantation step or multiple ion implantation steps.

8. The method of claim 1 wherein the room temperature oxygen ion implantation step is performed utilizing a single ion implantation step or multiple ion implantation steps.

9. The method of claim 1 wherein annealing process comprises a ramp-up anneal, an internal oxidation, annealing and a ramp-down step.

10. The method of claim 1 wherein said annealing process forms a surface oxide on said Si-containing substrate.

11. The method of claim 10 further comprising a step of removing said surface oxide from said Si-containing substrate by planarization or selective etching.

12. The method of claim 1 wherein step (a) is selected to achieve said breakdown field and said oxygen ion dose is from about 2.0E17 to about 2.4E17 cm⁻².

13. The method of claim 1 wherein step (a) is performed in an ion beam apparatus that operates at a beam current from about 1 to about 100 milliamps and an energy from about 1 to about 10,000 keV.

14. The method of claim 1 wherein step (a) is performed at a substrate temperature from about 100° to about 800° C.

15. The method of claim 1 wherein step (b) is selected to achieve said breakdown field and said energy is off-set to a value from about 6 to about 8% lower than the energy of said base oxygen ion implantation step.

16. The method of claim 1 wherein step (b) is selected to achieve said breakdown field and said energy is from about 155 to about 165 keV.

17. The method of claim 1 wherein step (b) is performed using an oxygen ion dose from about 1E15 to about 5E15 cm⁻².

18. The method of claim 1 wherein step (b) is performed at a temperature from about 1 Kelvin to about 200° C.

19. The method of claim 1 wherein step (c) is selected to achieve said breakdown field and said annealing process includes a ramp-up step, said pre-annealing soak, said internal oxidation annealing, annealing and a cool-down step.

20. The method of claim 19 wherein said pre-annealing soak is performed at a temperature of about 1250° C. or greater.

21. The method of claim 19 wherein said pre-annealing soak is performed for a time period from about 5 minutes to about 5 hours.

22. The method of claim 19 wherein said ramp-up step, said pre-annealing soak, said annealing and said cool-down step are performed in the same or different ambient that comprises an inert gas containing less than 10% oxygen.

23. The method of claim 19 wherein said pre-annealing soak is performed in an ambient containing greater than 30% oxygen.

24. A method of fabricating a silicon-on-insulator substrate (SOI) comprising the steps of:
(a) subjecting a Si-containing substrate to a base oxygen ion implantation step to create a first structure having a damaged implant region within the Si-containing substrate;
(b) subjecting the first structure to a room temperature oxygen ion implantation step to create a second structure having an amorphized implant region adjacent to said damaged implanted region, wherein said room temperature oxygen implant step is performed at an energy that is about 5 to about 20% less than an energy used during the base oxygen ion implantation step; and
(c) performing an annealing process on said second structure, wherein an SOI substrate is provided that comprises a buried oxide having a breakdown field of greater than 5 MV/cm.

25. A method for fabricating a silicon-on-insulator (SOI) substrate comprising the steps of:
(a) subjecting a Si-containing substrate to a base oxygen ion implantation step to create a first structure having a damaged implant region within the Si-containing substrate;
(b) subjecting the first structure to a room temperature oxygen ion implantation step to create a second structure having an amorphized implant region adjacent to said damaged implanted region; and
(c) performing an annealing process on said second structure, said annealing process includes a pre-annealing soak cycle employed prior to an internal oxidation step, wherein an SOI substrate is provided that comprises a buried oxide having a breakdown field of greater than 5 MV/cm.

26. A method for fabricating a silicon-on-insulator substrate comprising the steps of:
(a) subjecting a Si-containing substrate to a base oxygen ion implantation step to create a first structure having a damaged implant region within the Si-containing substrate;
(b) subjecting the first structure to a room temperature oxygen ion implantation step to create a second structure having an amorphized implant region adjacent to said damaged implanted region, said room temperature oxygen ion implantation step is performed at an energy that is about 5 to about 20% less than an energy used during the base oxygen ion implantation step; and
(c) performing an annealing process on said second structure, said annealing process includes a pre-annealing soak cycle employed prior to an internal oxidation step, wherein an SOI substrate is provided comprises a buried oxide having a breakdown field of greater than 5 MV/cm.

27. A method for fabricating a silicon-on-insulator substrate comprising the steps of:
(a) subjecting a Si-containing substrate to a base oxygen ion implantation step to create a first structure having a damaged implant region within the Si-containing substrate, said base oxygen ion implantation step is performed using an ion dose of about 2.5 cm⁻² or less at an energy of 170 keV or greater;
(b) subjecting the first structure to a room temperature oxygen ion implantation step to create a second structure having an amorphized implant region adjacent to said damaged implanted region, said room temperature oxygen ion implantation step is performed at an energy that is about 5 to about 20% less than an energy used during the base oxygen ion implantation step; and
(c) performing an annealing process on said second structure, said annealing process includes a pre-annealing soak cycle employed prior to an internal oxidation step, wherein an SOI substrate is provided comprises a buried oxide having a breakdown field of greater than 5 MV/cm.
